(19) United States
(12) Patent Application Publication
(10) Pub. No.: US 2008/0057183 A1
(43) Pub. Date: Mar. 6, 2008

(54) METHOD FOR LITHIUM DEPOSITION IN OLED DEVICE

(76) Inventors: Jeffrey P. Spindler, Rochester, NY (US); Tukaram K. Hatwar, Penfield, NY (US)

Correspondence Address: Pamela R. Crocker;Patent Legal Staff, Eastman Kodak Company, 343 State Street, Rochester, NY, 14650-2201, US

(21) Appl. No.: 11/468,899

(22) Filed: Aug. 31, 2006

(51) Int. Cl. B05D 5/12; C23C 16/00

(52) U.S. Cl. 427/64; 427/66; 427/248.1

(57) ABSTRACT

A method for use in making an OLED device by depositing lithium to form a lithium-doped organic layer comprising: providing multiple sources in the same vacuum chamber, at least one of which is for depositing organic material and another source for depositing lithium; and using such multiple sources to co-deposit lithium and the organic material to form the lithium-doped organic layer such that lithium provided by the lithium source does not contaminate other deposited organic layers in the OLED device.

### CROSS REFERENCE TO RELATED APPLICATIONS

Reference is made to commonly assigned U.S. patent application Ser. No. 11/393,767 filed 30 Mar. 2006 by Hatwar et al.; the disclosures of which are incorporated herein by reference.

### FIELD OF THE INVENTION

The present invention relates to a method for forming a lithium layer in an OLED device.

### BACKGROUND OF THE INVENTION

While organic electroluminescent (EL) devices have been known for over two decades, their performance limitations have represented a barrier to many desirable applications. In simplest form, an organic EL device is comprised of an anode for hole injection, a cathode for electron injection, and an organic medium sandwiched between these electrodes to support charge recombination that yields emission of light. These devices are also commonly referred to as organic light-emitting diodes, or OLEDs. Representative of earlier organic EL devices are Gurnee et al. U.S. Pat. No. 3,172,862, issued Mar. 9, 1965; Gurnee U.S. Pat. No. 3,173,050, issued Mar. 9, 1965; Dresner, “Double Injection Electroluminescence in Anthracene”, RCA Review, 30, 322, (1969); and Dresner U.S. Pat. No. 3,710,167, issued Jan. 9, 1973. The organic layers in these devices, usually composed of a polycyclic aromatic hydrocarbon, were very thick (much greater than 1 μm). Consequently, operating voltages were very high, often greater than 100V.

More recent organic EL devices include an organic EL element consisting of extremely thin layers (e.g. <1.0 μm) between the anode and the cathode. Herein, the term “organic EL element” encompasses the layers between the anode and cathode. Reducing the thickness lowered the resistance of the organic layers and has enabled devices that operate at much lower voltage. In a basic two-layer EL device structure, described first in U.S. Pat. No. 4,356,429, one organic layer of the EL element adjacent to the anode is specifically chosen to transport holes, and therefore is referred to as the hole-transporting layer, and the other organic layer is specifically chosen to transport electrons and is referred to as the electron-transporting layer. Recombination of the injected holes and electrons within the organic EL element results in efficient electroluminescence. There have also been proposed three-layer organic EL devices that contain an organic light-emitting layer (LEL) between the hole-transporting layer and electron-transporting layer, such as that disclosed by C. Tang et al. (J. Applied Physics, Vol. 65, 3610 (1989)), and in U.S. Pat. No. 4,769,292 a four-layer EL element comprising a hole injecting layer (HIL), a hole-transporting layer (HTL), a light-emitting layer (LEL) and an electron-transporting/injecting layer (ETL). These structures have resulted in improved device efficiency.

Since these early inventions, further improvements in device materials have resulted in improved performance in attributes such as color, stability, luminance efficiency and manufacturability, e.g., as disclosed in U.S. Pat. No. 5,061,569, U.S. Pat. No. 5,409,783, U.S. Pat. No. 5,554,450, U.S. Pat. No. 5,593,788, U.S. Pat. No. 5,683,823, U.S. Pat. No. 5,908,581, U.S. Pat. No. 5,928,802, U.S. Pat. No. 6,020,078, and U.S. Pat. No. 6,208,077, amongst others. For example, a useful class of electron-transporting materials is that derived from metal-chelated oxinoid compounds including chelates of oxine itself, also commonly referred to as 8-quinolinol or 8-hydroxyquinoline. Tris(8-quinolinolato)aluminum (III), also known as Alq or Alq₃, and other metal and non-metal oxine chelates are well known in the art as electron-transporting materials. Tang et al., in U.S. Pat. No. 4,769,292 and VanSlyke et al., in U.S. Pat. No. 4,539,507 teach lowering the drive voltage of the EL devices by the use of Alq as an electron-transporting material in the luminescent layer or luminescent zone.

Alkali metals such as lithium have been found to be quite useful in a number of applications in OLED devices. Liao et al., in U.S. Pat. No. 6,936,961, teach the use of a lithium dopant to an Alq layer to form an n-type doped organic layer. Lithium is also known in the art to be used as electron-injecting material in OLED devices. OLED devices are known that use a lithium layer as an electron injection layer between the organic light-emitting materials and the cathode.

Lithium deposition, however, is difficult to control in a manufacturing environment. It can contaminate deposition chambers used for the manufacture of OLED devices, remain in the deposition environment after deposition is turned off, and be deposited in other OLED layers in which it is not wanted and may even be deleterious. Therefore, there remains a need for improved methods of lithium deposition in the manufacture of these devices.

### SUMMARY OF THE INVENTION

It is therefore an object of the invention to isolate lithium deposition from deposition of other organic layers in making OLED devices.

This object is achieved by a method for use in making an OLED device by depositing lithium to form a lithium-doped organic layer comprising:

a. providing multiple sources in the same vacuum chamber, at least one of which is for depositing organic material and another source for depositing lithium; and

b. using such multiple sources to co-deposit lithium and the organic material to form the lithium-doped organic layer such that lithium provided by the lithium source does not contaminate other deposited organic layers in the OLED device.

This object is also achieved by a method for use in making an OLED device by depositing lithium to form a lithium layer on an organic layer comprising:

a. providing multiple sources, at least one of which is for depositing organic material and forming the organic layer, and another source, isolated from the organic material source, that vaporizes lithium; and

b. using such multiple sources to deposit the organic layer and the lithium layer such that lithium provided by the lithium source does not contaminate other deposited organic layers in the OLED device.

### Advantages

It is an advantage of this invention that a layer of lithium, or a lithium-doped organic layer, can be deposited onto an OLED device while reducing the likelihood of contaminating other layers with lithium. This can make it easier to manufacture OLED devices on a large scale. It is a further advantage of this invention that it improves the manufacturing yield of OLED devices. It is a further advantage of this invention that it improves the reproducibility of OLED device manufacturing.

### BRIEF DESCRIPTION OF THE DRAWINGS

FIG. 1 shows a cross-sectional view of one embodiment of an apparatus that can be used in accordance with the method of this invention;

FIG. 2 shows a cross-sectional view of another embodiment of an apparatus that can be used in accordance with the method of this invention;

FIG. 3 shows a cross-sectional view of one embodiment of an OLED device that can be prepared in accordance with the method of this invention;

FIG. 4 shows a cross-sectional view of another embodiment of an OLED device that can be prepared in accordance with the method of this invention;

FIG. 5 shows a cross-sectional view of another embodiment of an OLED device that can be prepared in accordance with the method of this invention;

FIG. 6 shows a block diagram of one embodiment of a method for making an OLED device by depositing lithium in accordance with this invention; and

FIG. 7 shows a block diagram of another embodiment of a method for making an OLED device by depositing lithium in accordance with this invention.

Since device feature dimensions such as layer thicknesses are frequently in sub-micrometer ranges, the drawings are scaled for ease of visualization rather than dimensional accuracy.

### DETAILED DESCRIPTION OF THE INVENTION

The term “OLED device” or “organic light-emitting display” is used in its art-recognized meaning of a display device comprising organic light-emitting diodes as pixels. A color OLED device emits light of at least one color. The term “multicolor” is employed to describe a display panel that is capable of emitting light of a different hue in different areas. In particular, it is employed to describe a display panel that is capable of displaying images of different colors. These areas are not necessarily contiguous. The term “full color” is commonly employed to describe multicolor display panels that are capable of emitting in the red, green, and blue regions of the visible spectrum and displaying images in any combination of hues. However, the use of additional colors to extend the color gamut of the device is possible. Broadband emission is light that has significant components in multiple portions of the visible spectrum, for example, blue and green. Broadband emission can also include the situation where light is emitted in the red, green, and blue portions of the spectrum in order to produce white light. White light is that light that is perceived by a user as having a white color, or light that has an emission spectrum sufficient to be used in combination with color filters to produce a practical full color display. For low power consumption, it is often advantageous for the chromaticity of the white light-emitting OLED to be close to Illuminant D₆₅, i.e., CIE x=0.31 and CIE y=0.33, although the actual coordinates can vary significantly and still be very useful.

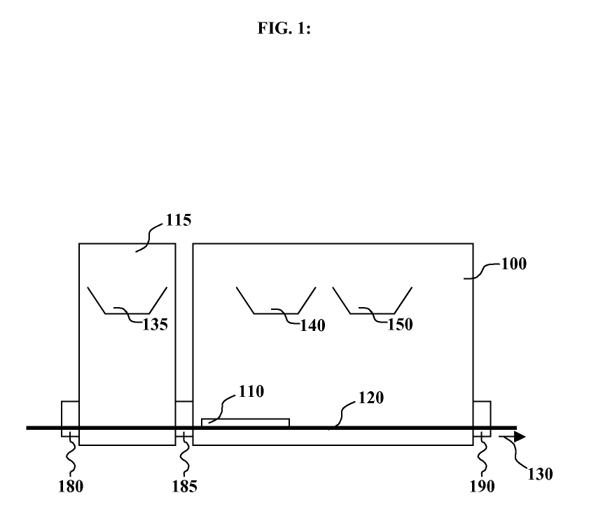

Turning now to FIG. 1, there is shown a cross-sectional view of one embodiment of an apparatus that can be used in accordance with the method of this invention. Vacuum chamber 100 can be used in making an OLED device by depositing lithium to form a lithium-doped organic layer. Vacuum chamber 100 provides multiple sources in the same vacuum chamber, at least one of which is for depositing organic material (organic material source 140), and another source that vaporizes lithium for depositing lithium (lithium source 150). Organic material source 140 can vaporize organic material to form an organic layer on OLED structure 110. As used herein, the term “OLED structure” refers to a not-yet-complete OLED device, e.g. an OLED substrate with some but not all of the layers necessary to form an OLED device. In one convenient embodiment, the organic material deposited by organic material source 140 can comprise an electron-transporting material, which will be described further below, and thus the organic layer formed will be an electron-transporting layer. A separate lithium source 150 is located in close proximity to organic material source 140 so that the multiple sources are used to co-deposit lithium and organic material to form a lithium-doped organic layer, e.g. a lithium-doped electron-transporting layer.

Vacuum chamber 100 can be part of a larger multi-chamber apparatus for making OLED devices, such as described by Boroson et al. in U.S. patent application Ser. No. 10/414,699, filed 16 Apr. 2003. Other organic and non-organic layers can be deposited in vacuum chambers other than lithium-deposition vacuum chamber 100 in the larger apparatus. Such other organic layers can include hole-transporting layers and light-emitting layers, which can be negatively affected by the presence of lithium contamination. Non-organic layers can include electrode layers. The vacuum chambers for depositing such layers can be before or after vacuum chamber 100. As an example, vacuum chamber 115 includes organic material source 135. Organic material source 135 can deposit an organic layer, e.g. a light-emitting layer, on OLED structure 110. Such an organic layer is deposited on OLED structure 110 in vacuum chamber 115 before the OLED structure is introduced to vacuum chamber 100. Other vacuum chambers can precede vacuum chamber 115, or be used subsequent to vacuum chamber 100, for depositing other layers. A conveyance mechanism 120 can move OLED structure 110 from chamber to chamber in direction 130. Conveyance mechanism 120 can be e.g. a movable belt, a robotic arm, etc. Load locks, e.g. 180, 185, and 190, keep OLED structure 110 in a vacuum environment during transfer from chamber to chamber. The load locks also prevent the escape of lithium vapor, e.g. into vacuum chamber 115, such that lithium provided by lithium source 150 does not contaminate other deposited organic layers in the OLED device.

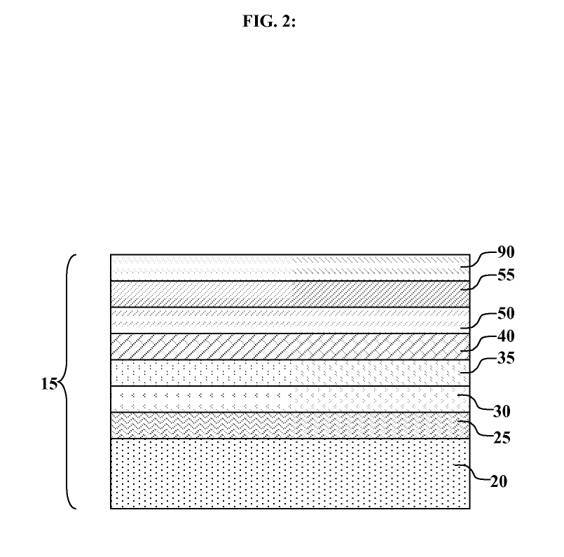

Turning now to FIG. 2, there is shown a cross-sectional view of one embodiment of an OLED device that can be prepared in accordance with the method of this invention, and in particular in part with the apparatus shown in FIG. 1. OLED device 15 includes at least a substrate 20, an anode 30, an organic layer that is an electron-transporting layer 55, another organic layer such as light-emitting layer 50, and a cathode 90. In this embodiment, electron-transporting layer 55 is a lithium-doped organic layer. OLED device 15 can also include other optional layers, such as color filter 25, hole-injecting layer 35, and hole-transporting layer 40. Hole-transporting layer 40 and those below (e.g. hole-injecting layer 35) are formed before the OLED structure enters vacuum chamber 115. Light-emitting layer 50 can be formed before OLED structure 110 enters vacuum chamber 115, or by organic material source 135 in vacuum chamber 115. In the latter case, organic material source 135 deposits light-emitting layer 50, after which the OLED structure is moved through load lock 185 into vacuum chamber 100 so that organic material source 140 and lithium source 150 co-deposit lithium and the organic material to form electron-transporting layer 55, which is the lithium-doped organic layer.

Electron-transporting layer 55 can contain one or more metal chelated oxinoid compounds, including chelates of oxine itself, also commonly referred to as 8-quinolinol or 8-hydroxyquinoline. Such compounds help to inject and transport electrons, exhibit high levels of performance, and are readily deposited to form thin films. Exemplary oxinoid compounds are the following:

CO-1: Aluminum trisoxine[alias, tris(8-quinolinolato)aluminum(III)];

CO-2: Magnesium bisoxine[alias, bis(8-quinolinolato)magnesium(II)];

CO-3: Bis[benzo{f}-8-quinolinolato]zinc (II);

CO-4: Bis(2-methyl-8-quinolinolato)aluminum(III)-m-oxo-bis(2-methyl-8-quinolinolato) aluminum(III);

CO-5: Indium trisoxine[alias, tris(8-quinolinolato)indium];

CO-6: Aluminum tris(5-methyloxine)[alias, tris(5-methyl-8-quinolinolato)aluminum(III)];

CO-7: Lithium oxine[alias, (8-quinolinolato)lithium(I)];

CO-8: Gallium oxine[alias, tris(8-quinolinolato)gallium(III)]; and

CO-9: Zirconium oxine[alias, tetra(8-quinolinolato)zirconium(IV)].

Other electron-transporting materials include various butadiene derivatives as disclosed in U.S. Pat. No. 4,356,429 and various heterocyclic optical brighteners as described in U.S. Pat. No. 4,539,507. Benzazoles, oxadiazoles, triazoles, pyridinethiadiazoles, triazines, phenanthroline derivatives, and some silole derivatives are also useful electron-transporting materials.

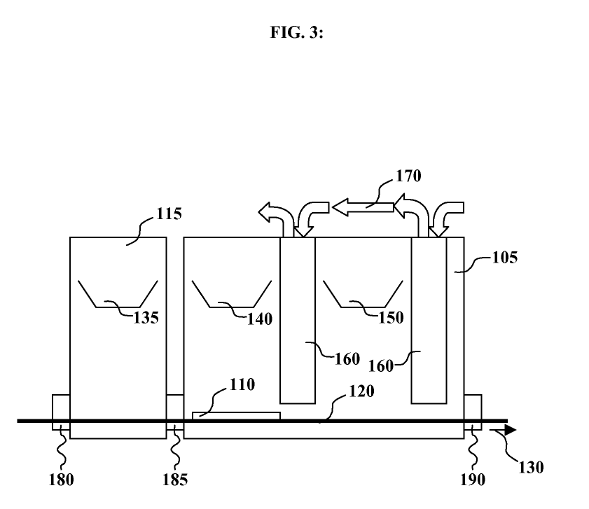

Turning now to FIG. 3, there is shown a cross-sectional view of another embodiment of an apparatus that can be used in accordance with the method of this invention, wherein multiple sources are provided. Vacuum chamber 105 can be used in making an OLED device by depositing organic material to form an organic layer, and depositing lithium to form a lithium layer on the organic layer. Vacuum chamber 105 provides the multiple sources. At least one, organic material source 140, is for depositing organic material and forming the organic layer. Another source, lithium source 150, is isolated from organic material source 140 and vaporizes lithium. Organic material source 140 can vaporize organic material to deposit such organic material and form an organic layer on an OLED structure. In one convenient embodiment, the organic material deposited by organic material source 140 can comprise an electron-transporting material. Lithium source 150 vaporizes lithium to form a lithium layer on the organic layer on OLED structure 110. Lithium source 150 is isolated from organic material source 140 by the presence of cold baffles 160 included in vacuum chamber 105 near lithium source 150. Other methods of isolation are also possible. For example, organic material source 140 and lithium source 150 can be in different chambers. Cold baffles 160 are kept cold by a coolant flow 170 and prevent the migration of lithium vapor to other parts of vacuum chamber 105, such as that part of vacuum chamber 105 in the vicinity of organic material source 140, or to other vacuum chambers. OLED structure 110 is introduced into vacuum chamber 105 in the vicinity of organic material source 140, where the organic layer is deposited on the OLED structure. After the organic layer is formed on OLED structure 110, conveyance mechanism 120 carries OLED structure 110 in direction 130 toward the region of lithium source 150, where the lithium layer is deposited on the organic layer. Conveyance mechanism 120 can be e.g. a movable belt, a robotic arm, etc. Excess lithium vaporized by lithium source 150 can be trapped by cold baffles 160 and does not contaminate other parts of vacuum chamber 105. Thus, the multiple sources deposit the organic layer and the lithium layer such that the lithium provided by lithium source 150 does not contaminate other deposited organic layers in the OLED device, and in particular other organic layers that are deposited in vacuum chambers other than lithium deposition vacuum chamber 105, either before depositing the organic layer from organic material source 140 or after depositing the lithium layer from lithium source 150. Such other organic layers can include hole-transporting layers and light-emitting layers, which can be negatively affected by the presence of lithium contamination. As an example, vacuum chamber 115 includes organic material source 135. Organic material source 135 can deposit an organic layer, e.g. a light-emitting layer, on OLED structure 110.

A small amount of lithium deposited on the organic layer at the top of OLED structure 110 can not only form a layer, but can also penetrate a short distance into the organic layer. The extent to which this occurs will depend upon the nature of the organic layer and upon the conditions inside vacuum chamber 100. Thus, a lithium layer deposited over an organic layer can also dope the organic layer.

Vacuum chamber 105 can be part of a larger multi-chamber apparatus for making OLED devices, such as described above.

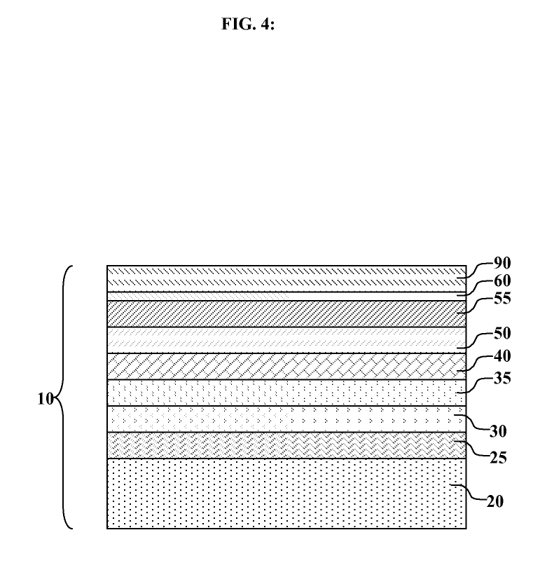

Turning now to FIG. 4, there is shown a cross-sectional view of another embodiment of an OLED device that can be prepared in accordance with the method of this invention, and in particular in part with the apparatus shown in FIG. 3. OLED device 10 includes at least a substrate 20, an anode 30, an organic layer that is an electron-transporting layer 55, a lithium layer 60, another organic layer such as light-emitting layer 50, and a cathode 90. OLED device 10 can also include other optional layers, such as color filter 25, hole-injecting layer 35, and hole-transporting layer 40. Hole-transporting layer 40 and those below (e.g. hole-injecting layer 35) are formed before the OLED structure enters vacuum chamber 115. Light-emitting layer 50 can be formed before OLED structure 110 enters vacuum chamber 115, or by organic material source 135 in vacuum chamber 115. In the latter case, organic material source 135 deposits light-emitting layer 50, after which the OLED structure is moved through load lock 185 into vacuum chamber 105. Organic material source 140 deposits electron-transporting layer 55, after which the OLED structure is moved through vacuum chamber 105 so that lithium source 150 deposits lithium layer 60.

OLED device layers that can be used in this invention have been well described in the art, and OLED device 10, and other such devices described herein, can include layers commonly used for such devices. OLED devices are commonly formed on a substrate, e.g. OLED substrate 20. Such substrates have been well-described in the art. A bottom electrode is formed over OLED substrate 20 and is most commonly configured as an anode 30, although the practice of this invention is not limited to this configuration. Example conductors for this application include, but are not limited to, gold, iridium, molybdenum, palladium, platinum, aluminum or silver. If the device is bottom-emitting, transparent electrode materials can be used, e.g. indium tin oxide or indium zinc oxide. Desired anode materials can be deposited by any suitable means such as evaporation, sputtering, chemical vapor deposition, or electrochemical means. Anode materials can be patterned using well-known photolithographic processes.

While not always necessary, it is often useful that a hole-transporting layer 40 be formed and disposed between the light-emitting layers and the anode. Desired hole-transporting materials can be deposited by any suitable means such as evaporation, sputtering, chemical vapor deposition, electrochemical means, thermal transfer, or laser thermal transfer from a donor material. Other hole-transporting materials useful in hole-transporting layers are well known to include compounds such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. in U.S. Pat. No. 3,180,730. Other suitable triarylamines substituted with one or more vinyl radicals and/or comprising at least one active hydrogen-containing group are disclosed by Brantley et al. in U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. Such compounds include those represented by structural Formula A.

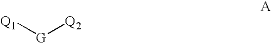

wherein:

Q₁ and Q₂ are independently selected aromatic tertiary amine moieties; and

G is a linking group such as an arylene, cycloalkylene, or alkylene group of a carbon to carbon bond.

In one embodiment, at least one of Q1 or Q2 contains a polycyclic fused ring structure, e.g., a naphthalene. When G is an aryl group, it is conveniently a phenylene, biphenylene, or naphthalene moiety.

A useful class of triarylamines satisfying structural Formula A and containing two triarylamine moieties is represented by structural Formula B.

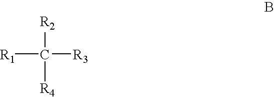

where:

R₁ and R₂ each independently represent a hydrogen atom, an aryl group, or an alkyl group or R₁ and R₂ together represent the atoms completing a cycloalkyl group; and

R₃ and R₄ each independently represent an aryl group, which is in turn substituted with a diaryl substituted amino group, as indicated by structural Formula C.

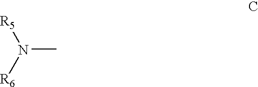

wherein R₅ and R₆ are independently selected aryl groups. In one embodiment, at least one of R₅ or R₆ contains a polycyclic fused ring structure, e.g., a naphthalene.

Another class of aromatic tertiary amines are the tetraaryldiamines. Desirable tetraaryldiamines include two diarylamino groups, such as indicated by Formula C, linked through an arylene group. Useful tetraaryldiamines include those represented by Formula D.

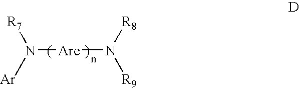

wherein:

each Are is an independently selected arylene group, such as a phenylene or anthracene moiety;

n is an integer of from 1 to 4; and

Ar, R₇, R₈, and R₉ are independently selected aryl groups.

In a typical embodiment, at least one of Ar, R₇, R₈, and R₉ is a polycyclic fused ring structure, e.g., a naphthalene. The various alkyl, alkylene, aryl, and arylene moieties of the foregoing structural Formulae A, B, C, and D can each in turn be substituted.

Another class of useful hole-transporting materials includes polycyclic aromatic compounds as described in EP 1 009 041. Tertiary aromatic amines with more than two amino groups can be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-emitting layers produce light in response to hole-electron recombination. The light-emitting layers are commonly disposed over the hole-transporting layer. Desired organic light-emitting materials can be deposited by any suitable means such as evaporation, sputtering, chemical vapor deposition, electrochemical means, or radiation thermal transfer from a donor material. Useful organic light-emitting materials are well known. As more fully described in U.S. Pat. Nos. 4,769,292 and 5,935,721, the light-emitting layers of the OLED device comprise a luminescent or fluorescent material where electroluminescence is produced as a result of electron-hole pair recombination in this region. The light-emitting layers can be comprised of a single material, but more commonly include a host material doped with a guest compound or dopant where light emission comes primarily from the dopant. The dopant is selected to produce color light having a particular spectrum. The host materials in the light-emitting layers can be an electron-transporting material, a hole-transporting material, or another material that supports hole-electron recombination. The dopant is usually chosen from highly fluorescent dyes, but phosphorescent compounds, e.g., transition metal complexes as described in WO 98/55561, WO 00/18851, WO 00/57676, and WO 00/70655 are also useful. Dopants are typically coated as 0.01 to 10% by weight into the host material. Host and emitting materials known to be of use include, but are not limited to, those disclosed in U.S. Pat. Nos. 4,768,292, 5,141,671, 5,150,006, 5,151,629, 5,405,709, 5,484,922, 5,593,788, 5,645,948, 5,683,823, 5,755,999, 5,928,802, 5,935,720, 5,935,721, 6,020,078, 6,475,648, 6,534,199, 6,661,023, U.S. Patent Application Publications 2002/0127427 A1, 2003/0198829 A1, 2003/0203234 A1, 2003/0224202 A1, and 2004/0001969 A1.

Metal complexes of 8-hydroxyquinoline and similar derivatives constitute one class of useful host materials capable of supporting electroluminescence, and are particularly suitable for light emission of wavelengths longer than 500 nm, e.g., green, yellow, orange, and red. Some examples of such complexes include CO-1 to CO-9, above.

Another class of useful host materials includes derivatives of anthracene, such as those described in U.S. Pat. Nos. 5,935,721, 5,972,247, 6,465,115, 6,534,199, 6,713,192, U.S. Patent Application Publications 2002/0048687 A1, 2003/0072966 A1, and WO 2004/018587 A1. Some examples include derivatives of 9,10-dinaphthylanthracene derivatives and 9-naphthyl-10-phenylanthracene. Other useful classes of host materials include distyrylarylene derivatives as described in U.S. Pat. No. 5,121,029, and benzazole derivatives, for example, 2,2′,2″-(1,3,5-phenylene)tris[1-phenyl-1H-benzimidazole].

Useful fluorescent dopants include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrylium and thiapyrilium compounds, fluorene derivatives, periflanthene derivatives, indenoperylene derivatives, bis(azinyl)amine boron compounds, bis(azinyl)methane boron compounds, derivatives of distryrylbenzene and distyrylbiphenyl, and carbostyryl compounds. Among derivatives of distyrylbenzene, particularly useful are those substituted with diarylamino groups, informally known as distyrylamines.

Examples of useful phosphorescent materials that can be used in light-emitting layers of this invention include, but are not limited to, those described in WO 00/57676 A1, WO 00/70655 A1, WO 01/41512 A1, WO 02/15645 A1, WO 01/93642A1, WO 01/39234 A2, WO 02/074015 A2, WO 02/071813 A1, U.S. Pat. Nos. 6,458,475, 6,573,651, 6,451,455, 6,413,656, 6,515,298, 6,451,415, 6,097,147, U.S. Patent Application Publications 2003/0017361 A1, 2002/0197511 A1, 2003/0072964 A1, 2003/0068528 A1, 2003/0124381 A1, 2003/0059646 A1, 2003/0054198 A1, 2002/0100906 A1, 2003/0068526 A1, 2003/0068535 A1, 2003/0141809 A1, 2003/0040627 A1, 2002/0121638 A1, EP 1 239 526 A2, EP 1 238 981 A2, EP 1 244 155 A2, JP 2003073387A, JP 2003073388A, JP 2003059667A, and JP 2003073665A. Useful phosphorescent dopants include, but are not limited to, transition metal complexes, such as iridium and platinum complexes.

In some cases it is useful for one or more of the LELs within an electroluminescent unit to emit broadband light, for example white light, in the case wherein the light emitted by at least one of the electroluminescent units is white. Multiple dopants can be added to one or more layers in order to produce a white-emitting OLED, for example, by combining blue- and yellow-emitting materials, cyan- and red-emitting materials, or red-, green-, and blue-emitting materials. White-emitting devices are described, for example, in EP 1 187 235, EP 1 182 244, U.S. Pat. Nos. 5,683,823, 5,503,910, 5,405,709, 5,283,182, 6,627,333, 6,696,177, 6,720,092, U.S. Patent Application Publications 2002/0186214 A1, 2002/0025419 A1, and 2004/0009367 A1. In preferred embodiments, white-emitting electroluminescent units have two or more light-emitting layers that combine to produce white light. In some of these systems, the host for one light-emitting layer is a hole-transporting material.

An upper electrode most commonly configured as a cathode 90 is formed over the electron-transporting layer. If the device is top-emitting, the electrode must be transparent or nearly transparent. For such applications, metals must be thin (preferably less than 25 nm) or one must use transparent conductive oxides (e.g. indium-tin oxide, indium-zinc oxide), or a combination of these materials. Optically transparent cathodes have been described in more detail in U.S. Pat. No. 5,776,623. Cathode materials can be deposited by evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

The OLED device can include other layers as well. For example, a hole-injecting layer 35 can be formed over the anode, as described in U.S. Pat. No. 4,720,432, U.S. Pat. No. 6,208,075, EP 0 891 121 A1, and EP 1 029 909 A1. An electron-injecting layer, such as alkaline or alkaline earth metals, alkali halide salts, or alkaline or alkaline earth metal doped organic layers, can also be present between the cathode and the electron-transporting layer. White light-emitting OLED devices can include one or more color filters 25, which have been well-described in the art.

This invention is not limited to two light-emitting layers, but can encompass three, four, or more light-emitting layers. For example, Hatwar et al. in U.S. patent application Ser. No. 11/393,767 has taught an OLED device with at least four light-emitting layers provided between the anode and the cathode, wherein each of the four light-emitting layers produces a different emission spectrum when current passes between the anode and cathode, and such spectra combine to form white light; and the four light-emitting layers include a red light-emitting layer with a red light-emitting material, a yellow light-emitting layer with a yellow light-emitting material, a blue light-emitting layer with a blue light-emitting material, and a green light-emitting layer with a green light-emitting material, arranged such that: i) each of the light-emitting layers is in contact with at least one other light-emitting layer, ii) the blue light-emitting layer is in contact with the green light-emitting layer, and iii) the red light-emitting layer is in contact with only one other light-emitting layer. Hatwar describes useful light-emitting materials for the various light-emitting layers.

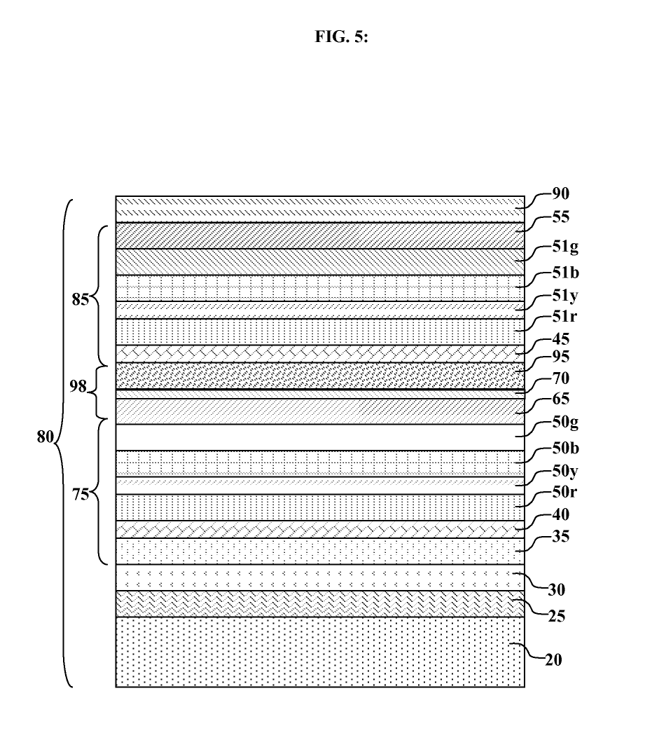

Turning now to FIG. 5, there is shown a cross-sectional view of another embodiment of an OLED device that can be prepared in accordance with the method of this invention, and in particular in part with the apparatus shown in FIG. 3. OLED device 80 is a tandem OLED device that includes a substrate 20, a spaced anode 30 and cathode 90, at least two white light-emitting units 75 and 85 disposed between the electrodes, and an intermediate connector 95 disposed between light-emitting units 75 and 85. Hatwar et al. in U.S. patent application Ser. No. 11/393,767 has described the use of multiple white light-emitting units of this arrangement. White light-emitting units 75 and 85 each produce emission spectra corresponding to white light. Each white light-emitting unit has four light-emitting layers: a red light-emitting layer (50r and 51r), a yellow light-emitting layer (50y and 51y), a blue light-emitting layer (50b and 51b), and a green light-emitting layer (50g and 51g). The light-emitting layers of white light-emitting units 75 and 85 can have the arrangement according to the criteria described by Hatwar et al. White light-emitting units 75 and 85 can have the same order of light-emitting layers, or can have different orders. Further, the light-emitting layers used can be the same or different (e.g. white light-emitting units 75 and 85 can have red light-emitting layers of the same or different composition, etc.). White light-emitting unit 85 includes electron-transporting layer 55 and hole-transporting layer 45. White light-emitting unit 75 includes electron-transporting layer 65. OLED device 80 further includes a lithium layer 70 above electron-transporting layer 65. Electron-transporting layer 65, lithium layer 70, and intermediate connector 95 form a connecting structure 98 between light-emitting units 75 and 85. Thus, connecting structure 98 includes a lithium layer 70 in contact with an organic layer (electron-transporting layer 65), which can be deposited by an apparatus as described in FIG. 3. Light-emitting layer 50g and those below (e.g. hole-transporting layer 40) are formed before the OLED structure enters vacuum chamber 100. Organic material source 140 deposits electron-transporting layer 65, after which the OLED structure is moved through vacuum chamber 100 so that lithium source 150 deposits lithium layer 70. The OLED structure can then be processed further in other chambers to deposit other layers to form the full OLED device. In another embodiment, the connecting structure includes a lithium-doped organic layer, as described above, instead of electron-transporting layer 65 and lithium layer 70. Such a lithium-doped organic layer can be deposited by an apparatus as described in FIG. 1. Light-emitting layer 50g and those below (e.g. hole-transporting layer 40) are formed before the OLED structure enters vacuum chamber 100. Organic material source 140 and lithium source 150 deposit a lithium-doped electron-transporting layer. The OLED structure can then be processed further in other chambers to deposit other layers to form the full OLED device.

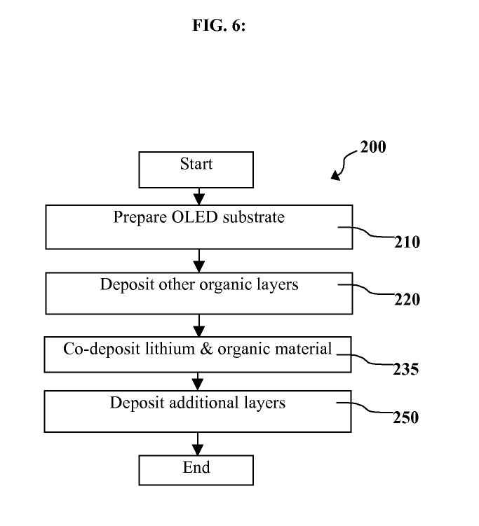

One embodiment of the method of this invention for use in making an OLED device is shown in FIG. 6. In method 200, an OLED substrate is prepared (Step 210) and one or more organic layers are deposited on it by methods well-known to those in the art to form an OLED structure (Step 220). For example, the apparatus described by Boroson in U.S. patent application Ser. No. 10/414,699 can be used for depositing the organic layers. The organic layers can include e.g. hole-injecting layer 35 and hole-transporting layer 40, as well as additional layers as described above. For example, a light-emitting layer 50 can be deposited in vacuum chamber 115 in FIG. 1. Those skilled in the art will understand that additional layers are possible and are frequently used. The OLED structure is then transferred to vacuum chamber 100, where an electron-transporting layer 55 doped with lithium is deposited on it (Step 235). The OLED structure 110 can then be transferred to another chamber where additional layers can be deposited, e.g. cathode 90 (Step 250).

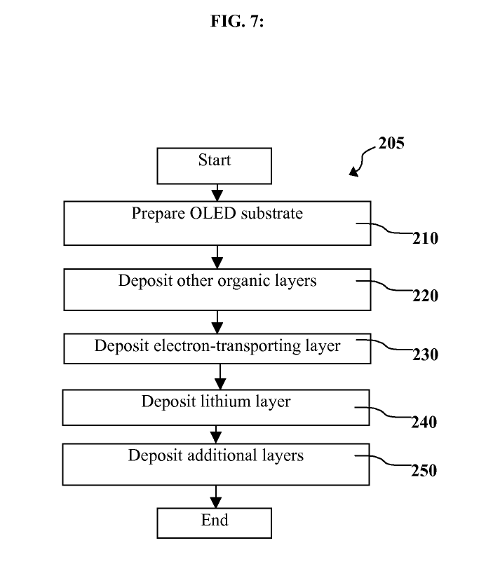

Another embodiment of the method of this invention for use in making an OLED device is shown in FIG. 7. In method 205, an OLED substrate is prepared (Step 210) and one or more organic layers are deposited on it by methods well-known to those in the art to form an OLED structure (Step 220). For example, the apparatus described by Boroson in U.S. patent application Ser. No. 10/414,699 can be used for depositing the organic layers. The organic layers can include e.g. hole-injecting layer 35, hole-transporting layer 40, and one or more light-emitting layers 50. For example, a light-emitting layer 50 can be deposited in vacuum chamber 115 in FIG. 3. Those skilled in the art will understand that additional layers are possible and are frequently used. The OLED structure is transferred to vacuum chamber 105, where first an electron-transporting layer 55 is deposited on it (Step 230), followed by a lithium layer 60 (Step 240). The OLED structure 110 can then be transferred to another chamber where additional layers can be deposited, e.g. cathode 90 (Step 250).

The invention has been described in detail with particular reference to certain preferred embodiments thereof, but it will be understood that variations and modifications can be effected within the spirit and scope of the invention.

### PARTS LIST

10 OLED device
15 OLED device
20 substrate
25 color filter
30 anode
35 hole-injecting layer
40 hole-transporting layer
45 hole-transporting layer
50 light-emitting layer
50b blue light-emitting layer
50g green light-emitting layer
50r red light-emitting layer
50y yellow light-emitting layer
51b blue light-emitting layer
51g green light-emitting layer
51r red light-emitting layer
51y yellow light-emitting layer
55 electron-transporting layer
60 lithium layer
65 electron-transporting layer
70 lithium layer
75 light-emitting unit
80 OLED device
85 light-emitting unit
90 cathode
95 intermediate connector
98 connecting structure
100 vacuum chamber
105 vacuum chamber
110 OLED structure
115 vacuum chamber
120 conveyance mechanism
130 direction
135 organic material source
140 organic material source
150 lithium source
160 cold baffles
170 coolant flow
180 load lock
185 load lock
190 load lock
200 method
205 method
210 block
220 block
230 block
235 block
240 block
250 block

What is claimed is:

1. A method for use in making an OLED device by depositing lithium to form a lithium-doped organic layer comprising:
a. providing multiple sources in the same vacuum chamber, at least one of which is for depositing organic material and another source for depositing lithium; and
b. using such multiple sources to co-deposit lithium and the organic material to form the lithium-doped organic layer such that lithium provided by the lithium source does not contaminate other deposited organic layers in the OLED device.

2. The method of claim 1 wherein the other organic layers are deposited in vacuum chambers other than the lithium deposition vacuum chamber.

3. The method of claim 1 wherein the organic layer is an electron-transporting layer.

4. The method of claim 3 wherein the OLED device is a tandem OLED device having a connecting structure including a lithium-doped organic layer.

5. The method of claim 1 wherein the OLED device is a tandem OLED device having a connecting structure including a lithium-doped organic layer.

6. A method for use in making an OLED device by depositing lithium to form a lithium layer on an organic layer comprising:
a. providing multiple sources, at least one of which is for depositing organic material and forming the organic layer, and another source, isolated from the organic material source, that vaporizes lithium; and
b. using such multiple sources to deposit the organic layer and the lithium layer such that lithium provided by the lithium source does not contaminate other deposited organic layers in the OLED device.

7. The method of claim 6 wherein the other organic layers are deposited in vacuum chambers other than the lithium deposition vacuum chamber.

8. The method of claim 6 wherein the organic layer is an electron-transporting layer.

9. The method of claim 8 wherein the OLED device is a tandem OLED device having a connecting structure including a lithium layer in contact with an organic layer.

10. The method of claim 6 wherein the OLED device is a tandem OLED device having a connecting structure including a lithium layer in contact with an organic layer.

11. The method of claim 6 wherein the vacuum chamber includes cold baffles near the lithium source.
